(19) United States
(12) Patent Application Publication
(10) Pub. No.: US 2014/0179215 A1
(43) Pub. Date: Jun. 26, 2014

(54) ELECTRONIC DEVICE ENCLOSURE

(71) Applicants: Hon Hai Precision Industry Co., Ltd., New Taipei (TW); Hong Fu Jin Precision Industry (WuHan) Co., Ltd., Wuhan (CN)

(72) Inventors: Lin Yu, Wuhan (CN); Zhi-Ping Wu, Wuhan (CN)

(73) Assignees: Hon Hai Precision Industry Co., Ltd., New Taipei (TW); Hong Fu Jin Precision Industry (WuHan) Co., Ltd., Wuhan (CN)

(21) Appl. No.: 13/958,293

(22) Filed: Aug. 2, 2013

(30) Foreign Application Priority Data
Dec. 20, 2012 (CN) 2012105577622

(51) Int. Cl. H05K 7/20

(52) U.S. Cl. CPC H05K 7/20009
USPC 454/184

(57) ABSTRACT

An electronic device enclosure includes a cabinet, an air guiding duct, and a controlling member. The cabinet includes a bottom plate with a heat dissipating area. The air guiding duct defines an ventilation hole and includes a side panel. An air outlet is defined in the side panel and communicates with the ventilation hole. The controlling member includes a shielding panel attached to the bottom plate and a shielding door connected to the shielding panel. The controlling member is rotatable relative to the bottom plate between in a first position and a second position. In the first position, the shielding door abuts the side panel to cover the air outlet, and the ventilation hole communicates with the heat dissipating area. In the second position, the shielding panel covers the ventilation hole, and the shielding door is disengaged from the side panel.

### BACKGROUND

1. Technical Field

The present disclosure relates to electronic device enclosures, and particularly to a vending mechanism with an air guiding duct.

2. Description of Related Art

Electronic devices, such as vending mechanisms, often comprise a condenser and a compressor. Usually, the condenser and the compressor have a large power capacity, and may generate high heat when working. The high heat may destroy the system of the vending mechanism. However, when a temperature outside the vending mechanism is low, the vending mechanism also needs to be heated to keep normal operation. It is a waste to exhaust heat generated by the condenser and the compressor out of the vending mechanism. Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, cutaway view of an electronic device enclosure in accordance with an embodiment.

FIG. 2 is similar to FIG. 1, but viewed from a different aspect.

FIG. 3 is an assembled view of the electronic device enclosure of FIG. 1, and the controlling member is located in a first position.

FIG. 4 is similar to FIG. 3, but viewed from a different aspect.

FIG. 5 is similar to FIG. 1, but the controlling member is located in a second position.

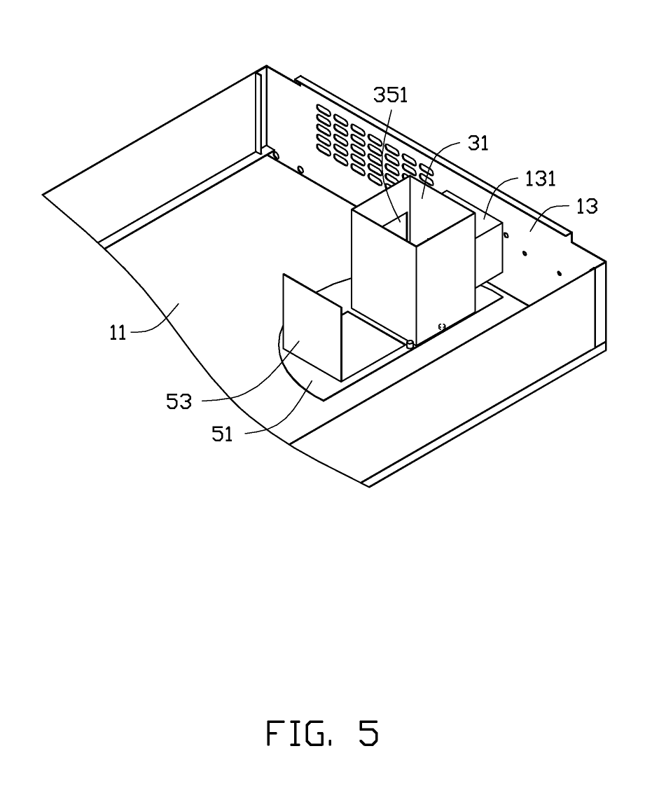

FIG. 6 is similar to FIG. 5, but viewed from a different aspect.

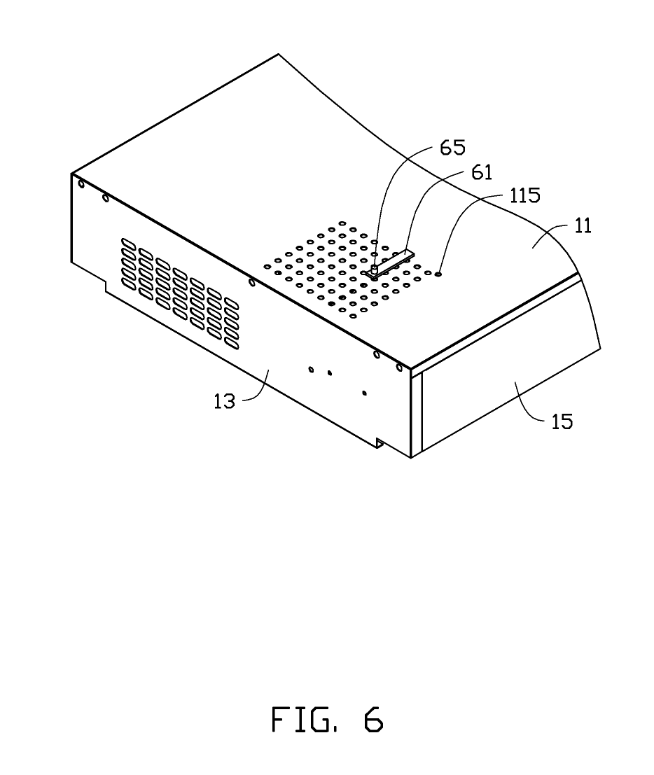

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

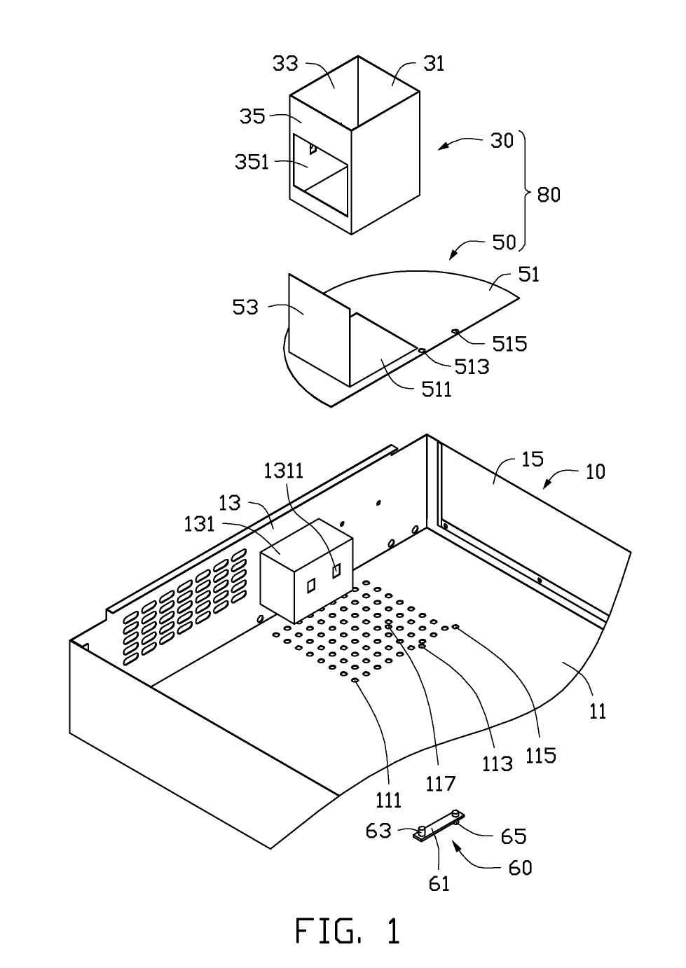

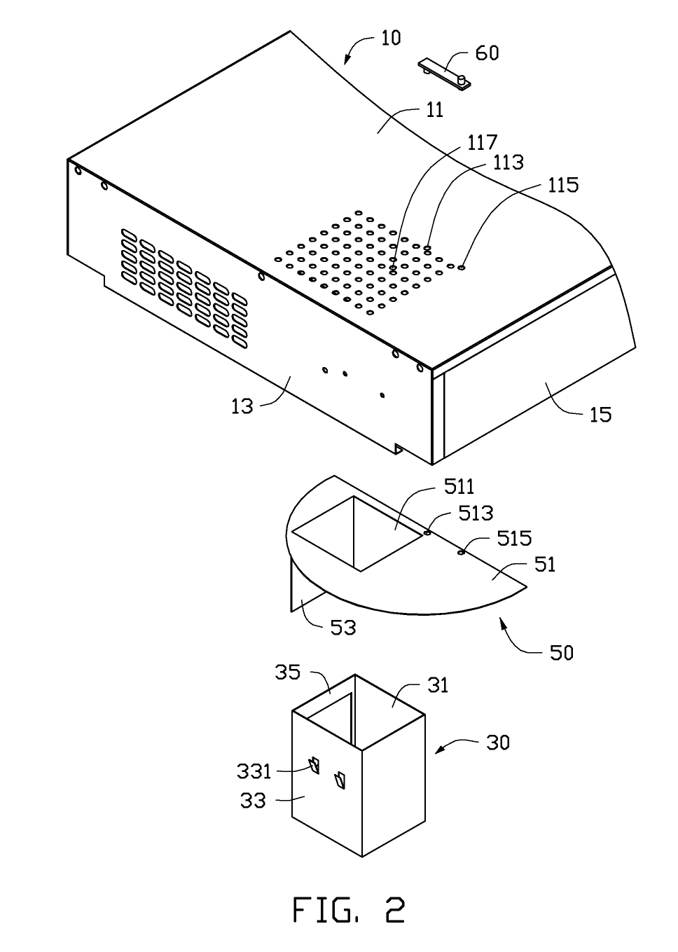

FIGS. 1-4 illustrate an electronic device enclosure in accordance with embodiments. The electronic device enclosure comprises a cabinet 10, a handle 60, and a control device 80.

The cabinet 10 comprises a bottom plate 11, a rear plate 13 connected to the bottom plate 11, and two opposite side plates 15 connected to two opposite edges of the bottom plate 11. The two side plates 15 are substantially parallel to each other and perpendicular to the bottom plate 11. A heat dissipating area 111 is defined in the bottom plate 11 and adjacent to the rear plate 13. In one embodiment, the heat dissipating area 111 is defined by a plurality of ventilation holes. A pivoting hole 113, a first through hole 115, and a second through hole 117 are defined in the bottom plate 11 and located in the heat dissipating area 111. In one embodiment, a connecting line which is connected to the pivoting hole 113, the first through hole 115 and the second through hole 117 can define a isosceles right triangle. A supporting member 131, with two clipping holes 1311, is attached to an inner surface of the rear plate 13.

The control device 80 comprises an air guiding duct 30, and a controlling member 50 rotatably attached to the cabinet 10.

The air guiding duct 30 defines an ventilation hole 31 and comprises a rear panel 33 and a side panel 35. Two elastic pieces 331 extends from the rear panel 33. In one embodiment, a sharp angle is defined between the rear panel 33 and each elastic piece 331. An air outlet 351, communicating with the ventilation hole 31, is defined in the side panel 35.

The controlling member 50 comprises a shielding panel 51 and a shielding door 53 located on the shielding panel 51. In one embodiment, the shielding panel 51 is substantially perpendicular to the shielding door 53. A cross-section of the shielding panel 51 is substantially a semi-circle. An opening 511 is defined in the shielding panel 51, and the shielding door 53 extends from an edge of the opening 511. The shielding panel 51 defines a mounting hole 513 and a positioning hole 515. A distance between the mounting hole 513 and the positioning hole 515 is substantially equal to a distance between the pivoting hole 113 and the first through hole 115, and also equal to a distance between the pivoting hole 113 and the second through hole 117.

The handle 60 comprises a pivoting panel 61, a pivoting post 63, and a securing member 65. The pivoting post 63 protrudes from a first end of the pivoting panel 61, and the securing member 65 is rotatably attached to a second opposite end of the pivoting panel 61. In one embodiment, a cross-section of the pivoting panel 61 is substantially a rectangle.

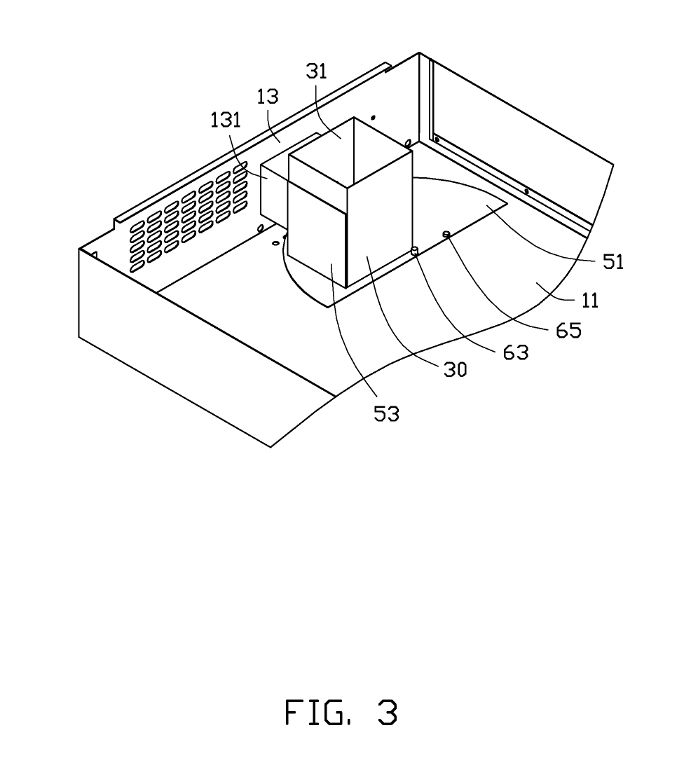

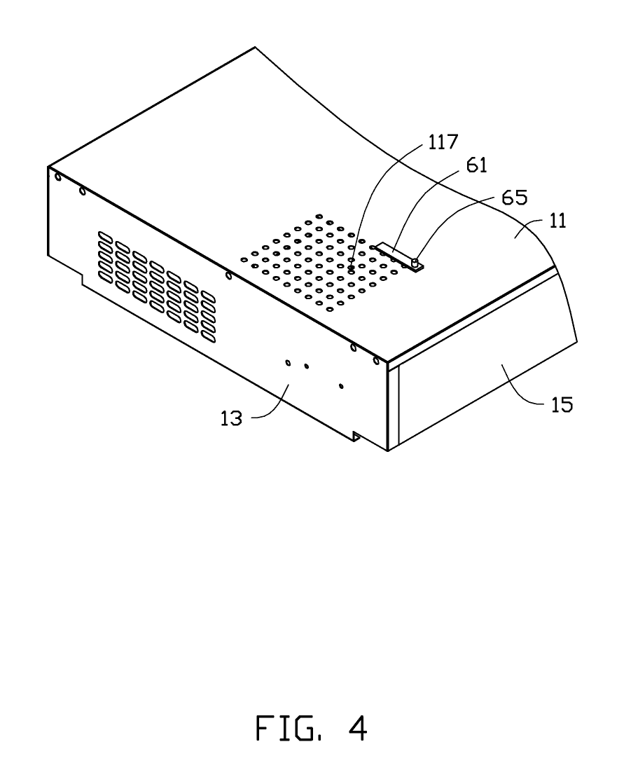

FIGS. 3-4 illustrate that in assembly, the pivoting post 63 extends through the pivoting hole 113 and clipped into the mounting hole 513, to secure the controlling member 50 to the bottom plate 11. The two elastic pieces 331 are clipped into the two clipping holes 1311, to secure the air guiding duct 30 to the supporting member 131. A first end of the air guiding duct 30 is adjacent to the controlling member 50, and a second opposite end of the air guiding duct 30 is adjacent to a fan (not shown).

When a temperature in the cabinet 10 is high, and the controlling member 50 is located in a first position, the shielding door 53 abuts the side panel 35 to cover the air out let 351. The ventilation hole 31 communicates with the opening 511 and the heat dissipating area 111. Thus, air in the cabinet 10 can flow out of the cabinet 10 via the heat dissipating area 111. The securing member 65 is engaged in the first through hole 115 and the positioning hole 515, to ensure the controlling member 50 is located in the first position.

FIGS. 3-4 illustrate that the controlling member 50 is located in a second position. When the temperature in the cabinet 10 is low, the securing member 65 is detached. The handle 60 is rotated about an axis that is substantially perpendicular to the bottom plate 11 and defined by the pivoting post 63, to position the controlling member 50 in the second position. The opening 511 is moved away from the ventilation hole 31, and the heat dissipating area 111 is separated from the opening 511 by the shielding panel 51. The shielding door 53 is disengaged from the side panel 35 to open the air outlet 351, and air in the ventilation hole 31 flows into the cabinet 10 via the air outlet 351. The securing member 65 is engaged in the second through hole 117 and the positioning hole 515, to ensure the controlling member 50 to be located in the second position.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device enclosure comprising:
a cabinet comprising a bottom plate; and the bottom plate defining a heat dissipating area;
an air guiding duct defining an ventilation hole; and the air guiding duct comprising a side panel; and an air outlet, defined in the side panel, communicating with the ventilation hole; and
a controlling member comprising a shielding panel attached to the bottom plate and a shielding door connected to the shielding panel;
wherein the controlling member is rotatable relative to the bottom plate between a first position and a second position; in the first position, the shielding door abuts the side panel to cover the air outlet, and the ventilation hole communicates with the heat dissipating area; and in the second position, the shielding panel covers the ventilation hole, and the shielding door is disengaged from the side panel.

2. The electronic device enclosure of claim 1, wherein the controlling member is rotatable about an axis that is substantially perpendicular to the bottom plate.

3. The electronic device enclosure of claim 2, further comprising a handle; wherein the bottom plate defines a pivoting hole; the shielding panel defines a mounting hole; and the handle comprises a pivoting post, the pivoting post extends through the mounting hole and is engaged in the pivoting hole to rotatably engage the controlling member to the bottom plate, and the axis is defined by the pivoting post.

4. The electronic device enclosure of claim 3, wherein the handle further comprises a pivoting panel and a securing member located in the pivoting panel; the bottom plate defines a first through hole and a second through hole; the shielding panel defines a positioning hole; when the controlling member is located in the first position, the securing member is engaged in the first through hole and the positioning hole; and when the controlling member is located in the second position, the securing member is engaged in the second through hole and the positioning hole.

5. The electronic device enclosure of claim 4, wherein a first distance between the first through hole and the pivoting hole is substantially equal to a second distance between the positioning hole and the mounting hole.

6. The electronic device enclosure of claim 4, wherein a connecting line connected to the pivoting hole, and the first through hole and the second through hole defines an isosceles right triangle.

7. The electronic device enclosure of claim 1, wherein the shielding panel defines an opening, when the controlling member is located in the first position, the ventilation hole communicates with the opening and the heat dissipating area; and when the controlling member is located in the second position, the opening is away from the ventilation hole.

8. The electronic device enclosure of claim 7, wherein the shielding door extends from an edge of the opening.

9. The electronic device enclosure of claim 1, wherein the shielding door is substantially perpendicular to the shielding panel.

10. The electronic device enclosure of claim 1, wherein the air guiding duct further comprises a rear panel; the rear panel comprises two elastic pieces; and a supporting member is located in the cabinet and defines two clipping holes, and the two elastic pieces are clipped into the two clipping holes.

11. An electronic device enclosure comprising:
a cabinet comprising a bottom plate; and the bottom plate defining a heat dissipating area;
an air guiding duct defining an ventilation hole; and the air guiding duct comprising a side panel and a rear panel connected to the side panel; and an air outlet, defined in the side panel, communicating with the ventilation hole, and the rear panel secured to the cabinet; and
a controlling member comprising a shielding panel attached to the bottom plate and a shielding door connected to the shielding panel; the shielding door abutting the side panel to cover the air outlet, the ventilation hole communicates with the heat dissipating area, to define a first air passage;
wherein the controlling member is rotatable relative to the bottom plate, so that the shielding panel covers the ventilation hole, the shielding door is disengaged from the side panel, and the ventilation hole communicates with the air outlet to define a second air passage.

12. The electronic device enclosure of claim 11, wherein the controlling member is rotatable about an axis that is substantially perpendicular to the bottom plate.

13. The electronic device enclosure of claim 12, further comprising a handle; wherein the bottom plate defines a pivoting hole; the shielding panel defines a mounting hole; and the handle comprises a pivoting post, the pivoting post extends through the mounting hole and is engaged in the pivoting hole to rotatably engage the controlling member to the bottom plate, and the axis is defined by the pivoting post.

14. The electronic device enclosure of claim 13, wherein the handle further comprises a pivoting panel and a securing member located in the pivoting panel; the bottom plate defines a first through hole and a second through hole; the shielding panel defines a positioning hole; the securing member extends through the positioning hole and selectly engaged in the first through hole or engaged in the second through hole.

15. The electronic device enclosure of claim 14, wherein a first distance between the first through hole and the pivoting hole is substantially equal to a second distance between the positioning hole and the mounting hole.

16. The electronic device enclosure of claim 14, wherein a connecting line connected to the pivoting hole, and the first through hole and the second through hole defines an isosceles right triangle.

17. The electronic device enclosure of claim 11, wherein the shielding panel defines an opening, when the ventilation hole communicates with the heat dissipating area, the opening is located between the ventilation hole and the heat dissipating area and communicates with the ventilation hole and the heat dissipating area; and when the ventilation hole communicates with the air outlet, the opening is away from the ventilation hole.

18. The electronic device enclosure of claim 17, wherein the shielding door extends from an edge of the opening.

19. The electronic device enclosure of claim 11, wherein the shielding door is substantially perpendicular to the shielding panel.

20. The electronic device enclosure of claim 11, wherein the rear panel comprises two elastic pieces; a supporting member is located in the cabinet and defines two clipping holes, and the two elastic pieces are clipped into the two clipping holes.
